(19) United States
(12) Patent Application Publication
(10) Pub. No.: US 2026/0282879 A1
(43) Pub. Date: Sep. 17, 2026

(54) SEMICONDUCTOR INTEGRATED CIRCUIT DEVICE

(71) Applicant: Socionext Inc., Kanagawa (JP)

(72) Inventor: Toshio HINO, Yokohama-shi (JP)

(21) Appl. No.: 19/668,922

(22) Filed: May 6, 2026

Related U.S. Application Data
(63) Continuation of application No. PCT/JP2024/041441, filed on Nov. 22, 2024.

(30) Foreign Application Priority Data
Dec. 8, 2023 (JP) 2023-207576

(51) Int. Cl. H10W 20/41; G11C 7/22; H10W 20/43; H10D 30/43

(52) U.S. Cl. CPC H10W 20/427; G11C 7/225; H10W 20/43; H10W 20/435; H10D 30/43

(57) ABSTRACT

In a semiconductor integrated circuit device having clock buffer cells, back-side interconnects are provided. The clock buffer cells each include: a first signal line serving as an input terminal, formed in an interconnect layer located on the front side of a transistor; and a second signal line serving as the input terminal, formed in an interconnect layer located on the back side of the transistor. The line width of the second signal line is larger than the line width of the first signal line.

### CROSS-REFERENCE TO RELATED APPLICATIONS

This is a continuation of International Application No. PCT/JP2024/041441 filed on Nov. 22, 2024, which claims priority to Japanese Patent Application No. 2023-207576 filed on Dec. 8, 2023. The entire disclosures of these applications are incorporated by reference herein.

### BACKGROUND

The present disclosure relates to a semiconductor integrated circuit device provided with a clock buffer cell.

In recent years, with the miniaturization of semiconductor devices, increase in power consumption, as well as speedup of circuits, are proceeding. To keep up with the circuit speedup, it is important to transmit a clock signal, which is supplied to flipflops, etc., with curbed clock skews. To curb clock skews, the drive capability of a clock buffer that transmits a clock signal is increased. With the increase in the drive capability of the clock buffer, however, a large current flows to the power supply for the clock buffer, and besides a large current also flows to the input/output terminals of the clock buffer. This makes obvious the problems of a power supply voltage drop (IR drop) and electromigration (EM).

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through lines, thereby designing an LSI chip.

WO 2021/192265 (Patent Document 1) discloses a clock buffer cell provided with an input terminal and an output terminal, in which the output terminal is formed in a layer above the input terminal and has a larger line width.

US Patent Application Publication No. 2021/0375853 (Patent Document 2) discloses a technique in which, for further higher integration, interconnects are provided on the back of the substrate immediately below transistors and the sources/drains of the transistors are connected to the interconnects.

In the technique of Patent Document 1, however, no mention is made of a structure of a clock buffer capable of curbing a power supply voltage drop and solving the problem of electromigration in a configuration having back-side interconnects like the one described in Patent Document 2.

An objective of the present disclosure is providing a semiconductor integrated circuit device provided with a clock buffer cell, in which, in a configuration having back-side interconnects, the problems of a power supply voltage drop and electromigration can be curbed.

### SUMMARY

According to the first mode of the disclosure, a semiconductor integrated circuit device includes a clock buffer cell having an input terminal and an output terminal, the clock buffer cell being a standard cell for transmitting a clock signal, wherein the clock buffer cell includes a transistor, a first signal line serving as the input terminal, formed in a first interconnect layer located on a front side of the transistor, and a second signal line serving as the input terminal, formed in a second interconnect layer located on a back side of the transistor, and the line width of the second signal line is larger than the line width of the first signal line.

According to the above mode, the clock buffer cell includes, as an input terminal: a first signal line formed in a first interconnect layer located on the front side of a transistor; and a second signal line formed in a second interconnect layer located on the back side of the transistor. The line width of the second signal line is larger than the line width of the first signal line. In a clock tree, when this clock buffer cell receives a clock signal output from a preceding clock buffer cell, a large current flows into the input terminal. By use of the second signal line large in line width as the input terminal, the problem of electromigration can be curbed.

According to the second mode of the disclosure, a semiconductor integrated circuit device includes a clock buffer cell having an input terminal and an output terminal, the clock buffer cell being a standard cell for transmitting a clock signal, wherein the clock buffer cell includes a transistor, a first signal line serving as the output terminal, formed in a first interconnect layer located on a front side of the transistor, and a second signal line serving as the output terminal, formed in a second interconnect layer located on a back side of the transistor, and the line width of the second signal line is larger than the line width of the first signal line.

According to the above mode, the clock buffer cell includes, as an output terminal: a first signal line formed in a first interconnect layer located on the front side of a transistor; and a second signal line formed in a second interconnect layer located on the back side of the transistor. The line width of the second signal line is larger than the line width of the first signal line. In a clock tree, when this clock buffer cell outputs a clock signal to a subsequent clock buffer cell, a large current flows through the output terminal. By use of the second signal line large in line width as the output terminal, the problem of electromigration can be curbed.

According to the present disclosure, in a semiconductor integrated circuit device provided with a clock buffer cell, in a configuration having back-side interconnects, the problems of a power supply voltage drop and electromigration can be curbed.

### BRIEF DESCRIPTION OF THE DRAWINGS

FIG. 1 is a circuit diagram of a clock tree including clock buffer cells.

FIG. 2 is a plan view showing a layout example of transistors and front-side interconnects of a clock buffer cell.

FIG. 3 is a plan view showing a layout example of back-side interconnects of the clock buffer cell.

FIGS. 4A-4B are enlarged plan views of a buffer part of the clock buffer cell of FIGS. 2 and 3, in which FIG. 4A shows transistors and front-side interconnects and FIG. 4B shows back-side interconnects.

FIG. 5 is a cross-sectional view showing a cross-sectional structure of the buffer part of FIGS. 4A-4B.

FIGS. 6A-6B are plan views showing a layout example of a normal standard cell, in which FIG. 6A shows transistors and front-side interconnects and FIG. 6B shows back-side interconnects.

FIG. 7 shows a block layout example of a semiconductor integrated circuit device according to an embodiment.

FIG. 8 shows an interconnect arrangement example of a BM1 interconnect layer in the block layout of FIG. 7.

FIG. 9 shows an interconnect arrangement example of BM2 and BM3 interconnect layers in the block layout of FIG. 7.

### DETAILED DESCRIPTION

An embodiment of the present disclosure will be described hereinafter with reference to the accompanying drawings. Note herein that “VDD” and “VSS” are used as symbols representing both the power supplies themselves and the power supply voltages applied by the power supplies. Note also that a standard cell is simply called a “cell” as appropriate.

While the semiconductor integrated circuit device is assumed to have nanosheet transistors in the following description, the transistors included in the semiconductor integrated circuit device according to the present disclosure are not limited to nanosheet transistors.

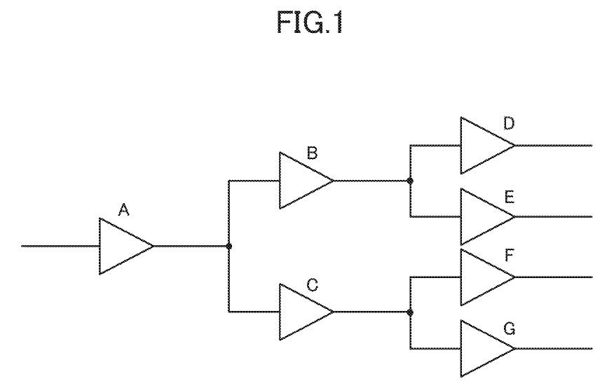

FIG. 1 is a circuit diagram showing an example of a clock tree including clock buffer cells. The clock tree receives an input clock generated by a clock generation circuit constituted by a phase locked loop (PLL) and the like, and outputs a plurality of output clocks to subsequent circuits through the clock buffer cells connected in a tree shape. The clock tree of FIG. 1 is constituted by three-stage clock buffer cells.

The first-stage clock buffer cell (A) and the second-stage clock buffer cells (B and C) are large in drive capability because they drive long interconnects and drive a number of buffers connected to their outputs. Therefore, a large current flows through the first- and second-stage clock buffer cells (A, B, and C) for charge/discharge for output loads. On the contrary, the third-stage clock buffer cells (D, E, F, and G) are small in drive capability because they drive short interconnects and the input capacities of circuits connected to their outputs are comparatively small. Therefore, no large current flows through the third-stage clock buffer cells (D, E, F, and G) for charge/discharge.

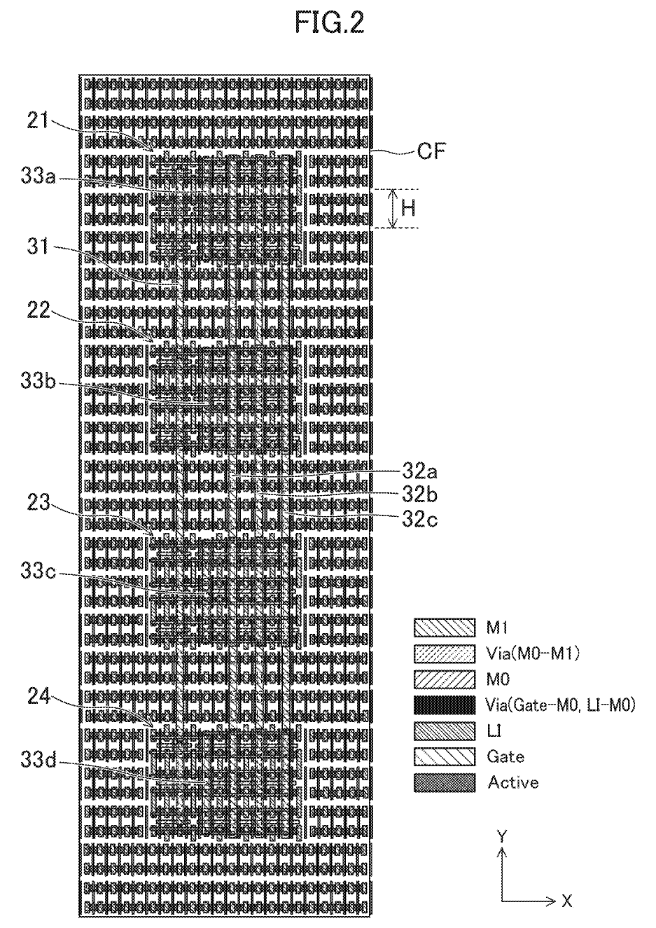

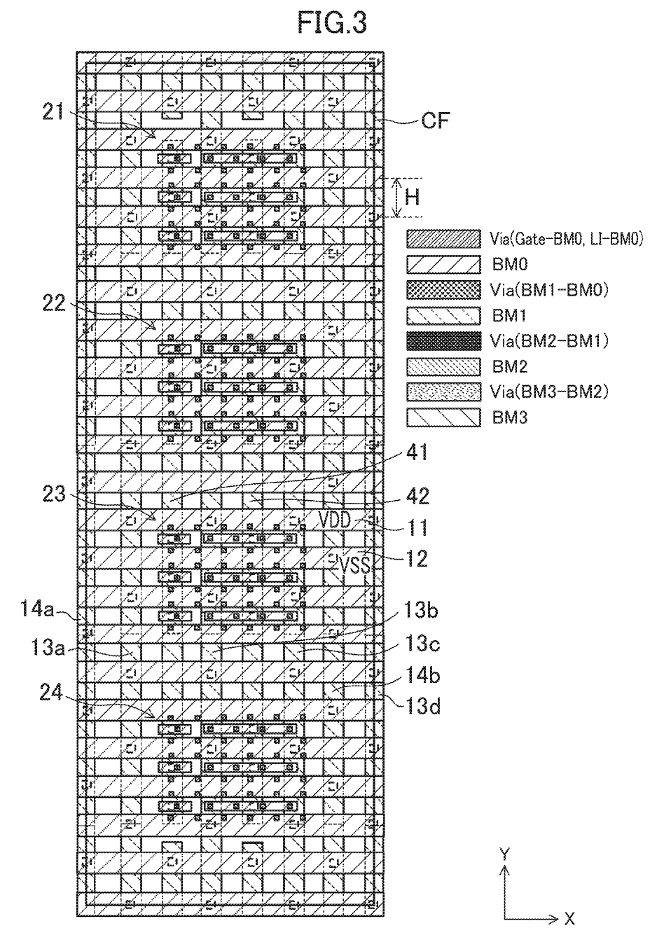

FIGS. 2 and 3 are plan views showing a layout of a clock buffer cell, in which FIG. 2 shows a layout of transistors and front-side interconnects and FIG. 3 is a layout of back-side interconnects. CF denotes a cell frame. As used herein, the front side of transistors refers to the side, with respect to the transistors, on which local interconnects and metal interconnects connected to the transistors are stacked one upon another, and the back side of transistors refers to the side, with respect to the transistors, opposite to the side on which local interconnects and metal interconnects connected to the transistors are stacked one upon another.

In this embodiment, as will be described later, power supply lines are formed in a BM0 interconnect layer that is a back-side interconnect layer. In the present disclosure, the region between power supply lines adjacent in the Y direction (corresponding to the second direction) is called a height region. In the height region, p-type field effect transistors (FETs) and n-type FETs are placed adjacently in the Y direction. H refers to the height of the height region. The clock buffer cell shown in FIGS. 2 and 3 is a multi-height cell having a cell height a plurality of times (22 times in the illustrated example) as large as H.

The clock buffer cell shown in FIGS. 2 and 3 includes four buffer parts 21, 22, 23, and 24.

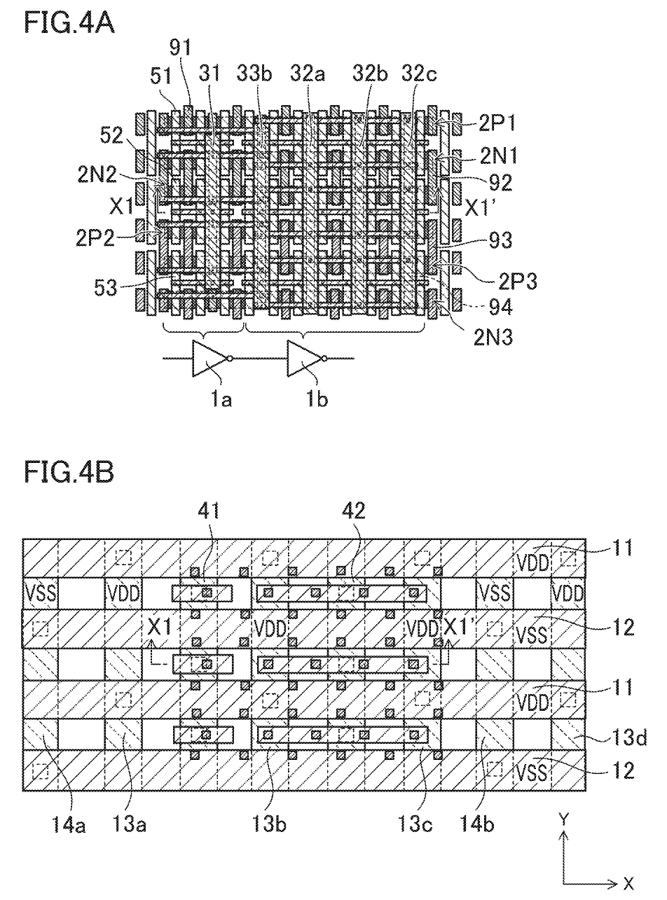

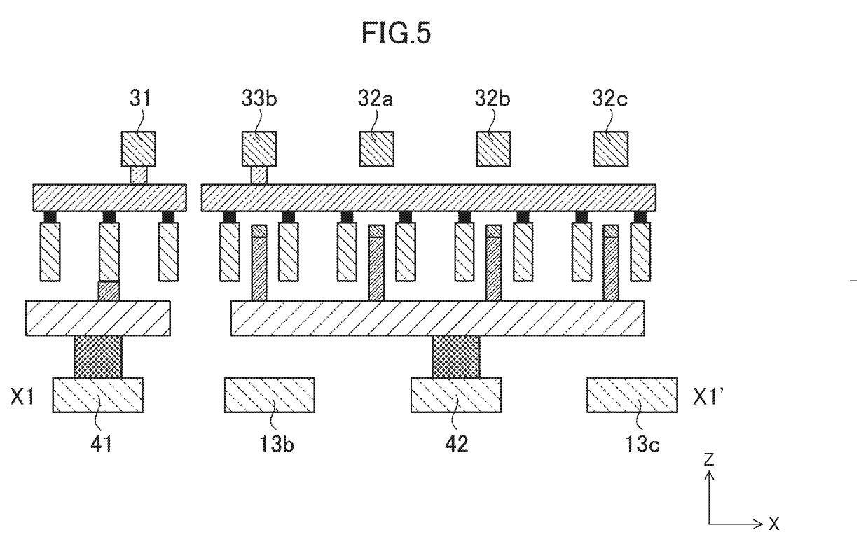

FIGS. 4A-4B are enlarged plan views of one buffer part, in which FIG. 4A shows a layout of transistors and front-side interconnects and FIG. 4B shows a layout of back-side interconnects. FIG. 5 is a cross-sectional view showing a cross-sectional structure taken along line X1-X1’ in FIGS. 4A and 4B. As a circuit, the buffer part has a configuration of serially connected inverters 1a and 1b as shown in FIG. 4A.

In the layout of FIG. 3, in the BM0 interconnect layer, power supply lines 11 that extend in the X direction (corresponding to the first direction) and supply VDD and power supply lines 12 that extend in the X direction and supply VSS are arranged alternately in the Y direction. The four buffer parts 21, 22, 23, and 24 are arranged in line in the Y direction. The height of the buffer parts 21, 22, 23, and 24 is 3H, and the spacing between the buffer parts 21, 22, 23, and 24 is 2H. Decoupling capacitor parts are formed around the buffer parts 21, 22, 23, and 24. The decoupling capacitor parts form capacitors between VDD and VSS, thereby curbing a power supply voltage drop.

In a BM1 interconnect layer located on the back side of the BM0 interconnect layer, signal lines 41 and 42 extending in the Y direction are placed. The signal line 41 corresponds to an input terminal of the clock buffer cell, and the signal line 42 corresponds to an output terminal of the clock buffer cell. The signal lines 41 and 42 extend over the four buffer parts 21, 22, 23, and 24.

Also, in the BM1 interconnect layer, placed are power supply lines 13a, 13b, 13c, and 13d supplying VDD extending in the Y direction and power supply lines 14a and 14b supplying VSS extending in the Y direction. The power supply lines 13a, 13b, 13c, and 13d are connected to the power supply lines 11 through vias, and the power supply lines 14a and 14b are connected to the power supply lines 12 through vias.

In the layout of FIG. 2, in an M1 interconnect layer that is a front-side interconnect layer, signal lines 31, 32a, 32b, and 32c extending in the Y direction are placed. The signal line 31 corresponds to the input terminal of the clock buffer cell, and the signal lines 32a, 32b, and 32c correspond to the output terminal of the clock buffer cell. The signal lines 31, 32a, 32b, and 32c extend over the four buffer parts 21, 22, 23, and 24. Note that an M0 interconnect layer is formed between the transistors and the M1 interconnect layer.

Also, in the M1 interconnect layer, signal lines 33a, 33b, 33c, and 33d extending in the Y direction are placed in the buffer parts 21, 22, 23, and 24, respectively. Each of the signal lines 33a, 33b, 33c, and 33d corresponds to an intermediate node between the inverter 1a and the inverter 1b in the buffer part.

As for the signal lines corresponding to the input terminal, the signal line 41 in the BM1 interconnect layer is larger in line width than the signal line 31 in the M1 interconnect layer. This is because of the difference in the magnitude of the flowing current: a larger current flows to the signal line 41. By increasing the line width of the signal line 41, therefore, the problem of electromigration can be curbed.

As for the signal lines corresponding to the output terminal, the signal line 42 in the BM1 interconnect layer is larger in line width than the signal lines 32a, 32b, and 32c in the M1 interconnect layer. This is also because of the difference in the magnitude of the flowing current: a larger current flows through the signal line 42. By increasing the line width of the signal line 42, therefore, the problem of electromigration can be curbed.

Also, in the BM1 interconnect layer, the power supply lines 13a and 13b are placed on both sides of the signal line 41 corresponding to the input terminal. The power supply lines 13band 13care placed on both sides of the signal line 42 corresponding to the output terminal. It is therefore possible to curb occurrence of crosstalk between the signal lines 41 and 42 through which a large current of a clock signal flows. Note that, although the power supply lines placed on both sides of each signal line are the VDD power supply lines in the illustrated example, the configuration is not limited to this. That is, VSS power supply lines may be placed on both sides of the signal line, or a VDD power supply line may be placed on one side of the signal line and a VSS power supply line may be placed on the other side.

Referring to FIGS. 4A-4B, the layout of the buffer parts will be described. Note that, while FIGS. 4A-4B shows a layout of the buffer part 22, the layouts of the other buffer parts are also similar to this layout.

In the buffer part, in the BM0 interconnect layer, the VDD power supply lines 11 and the VSS power supply lines 12 extend in the X direction and are arranged alternately in the Y direction. Above the power supply lines 11, active regions 2P1, 2P2, and 2P3 constituting the channels, sources, and drains of p-type nanosheet FETs are formed to extend in the X direction. Above the power supply lines 12, active regions 2N1, 2N2, and 2N3 constituting the channels, sources, and drains of n-type nanosheet FETs are formed to extend in the X direction.

Common gate interconnects 51 are provided for the active regions 2P1 and 2N1. The gate interconnects 51 extend in the Y direction and surround the peripheries of the nanosheets in the Y and Z directions through gate insulating films (not shown). Similarly, common gate interconnects 52 are provided for the active regions 2N2 and 2P2. The gate interconnects 52 extend in the Y direction and surround the peripheries of the nanosheets in the Y and Z directions through gate insulating films (not shown). Common gate interconnects 53 are provided for the active regions 2P3 and 2N3. The gate interconnects 53 extend in the Y direction and surround the peripheries of the nanosheets in the Y and Z directions through gate insulating films (not shown).

Each of the active regions 2P1, 2P2, 2P3, 2N1, 2N2, and 2N3 forms eleven nanosheet FETs lined in the X direction. Three columns of nanosheet FETs from left in the figure constitute the former-stage inverter 1a, and the remaining columns, i.e., eight columns of nanosheet FETs from right in the figure constitute the latter-stage inverter 1b.

In the active regions 2P1, 2P2, and 2P3, portions that serve as the sources of the p-type nanosheet FETs are connected to the power supply lines 11 formed in the BM0 interconnect layer through vias. In the active regions 2N1, 2N2, and 2N3, portions that serve as the sources of the n-type nanosheet FETs are connected to the power supply lines 12 formed in the BM0 interconnect layer through vias.

In the active regions 2P1, 2P2, 2P3, 2N1, 2N2, and 2N3, local interconnects 91 extending in the Y direction are connected to portions that serve as the sources or the drains. Common local interconnects 92 are connected to the active regions 2N1 and 2N2 adjacent in the Y direction, and common local interconnects 93 are connected to the active regions 2P2 and 2P3 adjacent in the Y direction. Also, in the eight columns of nanosheet FETs from right in the figure, common local interconnects 94 extending in the Y direction are connected to portions that serve as the drains.

In the M1 interconnect layer, the signal line 31 extends in the Y direction. As described above, the signal line 31 corresponds to the input terminal of the clock buffer cell. The signal line 31 is connected to the gate interconnects of the three columns of nanosheet FETs from left in the figure through vias, M0 interconnects extending in the X direction, and vias. The local interconnects connected to the portions that serve as the drains of the three columns of nanosheet FETs from left in the figure are connected to the signal line 33b extending in the Y direction through vias, M0 interconnects extending in the X direction, and vias. The signal line 33b corresponds to the intermediate node of the clock buffer cell as described above.

The signal line 33b is connected to the gate interconnects of the eight columns of nanosheet FETs from right in the figure through vias, M0 interconnects extending in the X direction, and vias. The local interconnects connected to the portions that serve as the drains of the eight columns of nanosheet FETs from right in the figure are connected to the signal lines 32a, 32b, and 32c extending in the Y direction through vias, M0 interconnects extending in the X direction, and vias. The signal lines 32a, 32b, and 32c correspond to the output terminal of the clock buffer cell as described above.

In the BM1 layer, the signal line 41 extends in the Y direction. As described above, the signal line 41 corresponds to the input terminal of the clock buffer cell. The signal line 41 is connected to the gate interconnects for one column of nanosheets, among the three columns of nanosheet FETs from left in the figure, through vias, BM0 interconnects, and vias. Also, in the BM1 layer, the signal line 42 extends in the Y direction. As described above, the signal line 42 corresponds to the output terminal of the clock buffer cell. The signal line 42 is connected to the local interconnects, which are connected to the drains of the eight columns of nanosheet FETs from right in the figure, through vias, BM0 interconnects extending in the X direction, and vias.

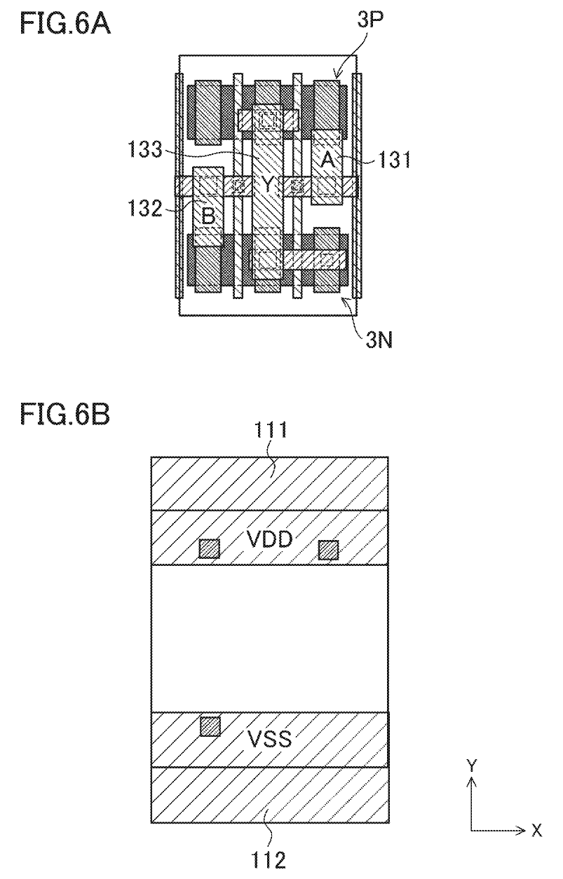

FIGS. 6A-6B show a layout example of a normal standard cell, in which FIG. 6A shows a layout of transistors and front-side interconnects and FIG. 6B shows a layout of back-side interconnects. FIGS. 6A-6B show a layout of a 2-input NAND cell having input terminals A and B and an output terminal Y.

As shown in FIGS. 6A-6B, in a BM0 interconnect layer, power supply lines 111 and 112 extending in the X direction are formed. The power supply line 111 supplies VDD and the power supply line 112 supplies VSS. Above the power supply line 111, an active region 3P constituting the channels, sources, and drains of p-type nanosheet FETs is formed to extend in the X direction. Above the power supply line 112, an active region 3N constituting the channels, sources, and drains of N-type nanosheet FETs is formed to extend in the X direction. In an M1 interconnect layer, signal lines 131, 132, and 133 extending in the Y direction are formed. The signal line 131 corresponds to the input A, the signal line 132 corresponds to the input B, and the signal line 133 corresponds to the output Y.

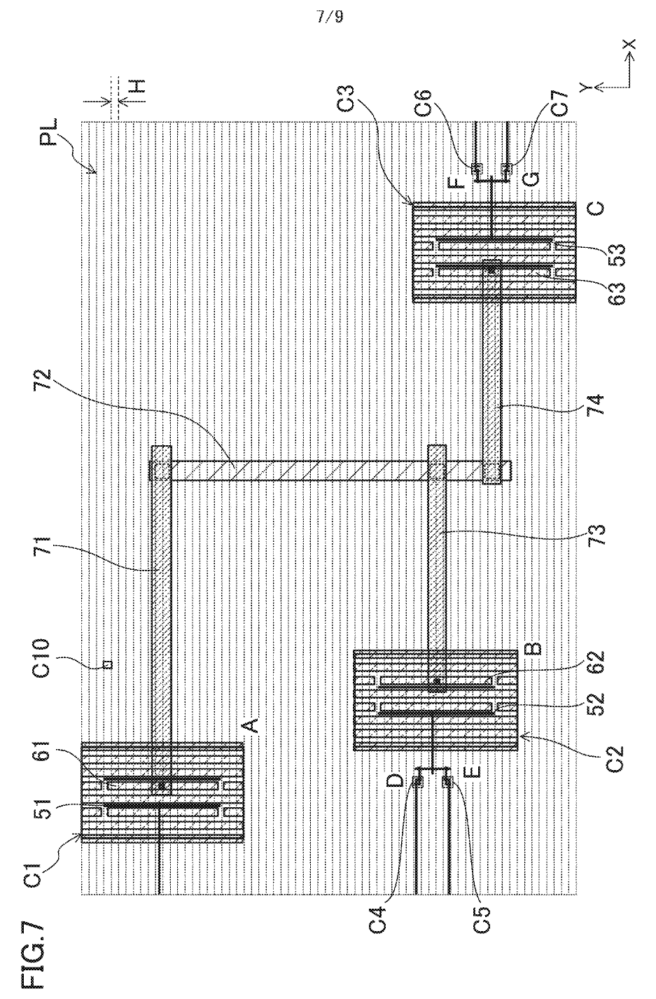

FIG. 7 shows a block layout example of the semiconductor integrated circuit device according to the embodiment. In FIG. 7, the fine broken lines extending in parallel in the X direction conceptually represent power supply lines PL. The power supply lines PL, formed in the BM0 interconnect layer, include power supply lines supplying VDD and power supply lines supplying VSS arranged alternately in the Y direction. Although illustration is omitted in FIG. 7, standard cells are placed in the height regions between the power supply lines. Most standard cells are single-height cells having a cell height equal to the height H of the height regions. For example, a cell C10 is a 2-input NAND cell shown in FIGS. 6A-6B.

In the block layout shown in FIG. 7, placed in addition to normal standard cells are three clock buffer cells C1, C2, and C3 that are multi-height cells having a cell height a plurality of times (22 times in the illustrated example) as large as H. The clock buffer cells C1, C2, and C3 respectively correspond to the buffer cells A, B, and C in the circuit diagram of FIG. 1. Also placed are cells C4, C5, C6, and C7 respectively corresponding to the buffer cells D, E, F, and G in the circuit diagram of FIG. 1. The cells C4, C5, C6, and C7 are single-height cells and smaller in drive capability than the clock buffer cells C1, C2, and C3.

The layouts of the clock buffer cells C1, C2, and C3 are as shown in FIGS. 2 to 5. In FIG. 7, however, the signal lines corresponding to the output terminal in the M1 interconnect layer are illustrated as a single line for the sake of simplification of the drawing.

The first-stage clock buffer cell C1 receives an input clock output from a clock generation circuit (not shown) at an M1 interconnect 51 that serves as the front-side input terminal. The clock buffer cell C1 outputs a clock from a BM1 interconnect 61 that serves as the back-side output terminal. The clock output from the BM1 interconnect 61 is transmitted to the second-stage clock buffer cells C2 and C3 through a BM2 interconnect 71 extending in the X direction, a BM3 interconnect 72 extending in the Y direction, and BM2 interconnects 73 and 74 extending in the X direction. The transmitted clock is input into a BM1 interconnect 62 that serves as the back-side input terminal of the clock buffer cell C2 and into a BM1 interconnect 63 that serves as the back-side input terminal of the clock buffer cell C3.

The clock buffer cell C2 outputs a clock from an M1 interconnect 52 that serves as the front-side output terminal. The clock output from the M1 interconnect 52 is transmitted to the cells C4 and C5. The clock buffer cell C3 outputs a clock from an M1 interconnect 53 that serves as the front-side output terminal. The clock output from the M1 interconnect 53 is transmitted to the cells C6 and C7.

Note that, although illustration is omitted, signal lines other than the lines between the clock buffer cells are formed in front-side interconnect layers. In back-side interconnect layers, no signal lines other than the lines between the clock buffer cells are formed. Since this can prevent occurrence of crosstalk between clock lines and other signal lines, clock skews can be reduced.

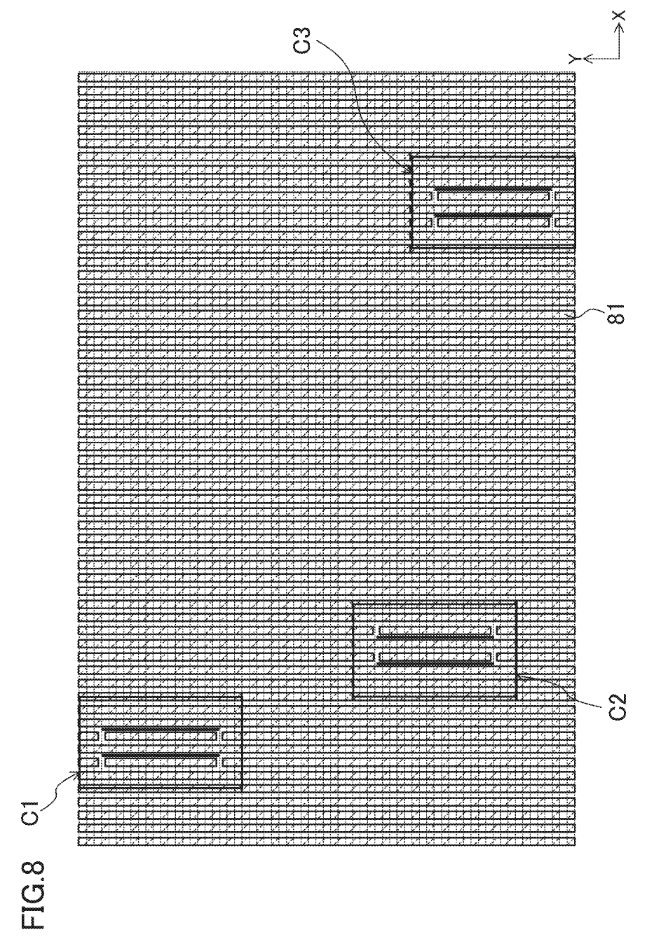

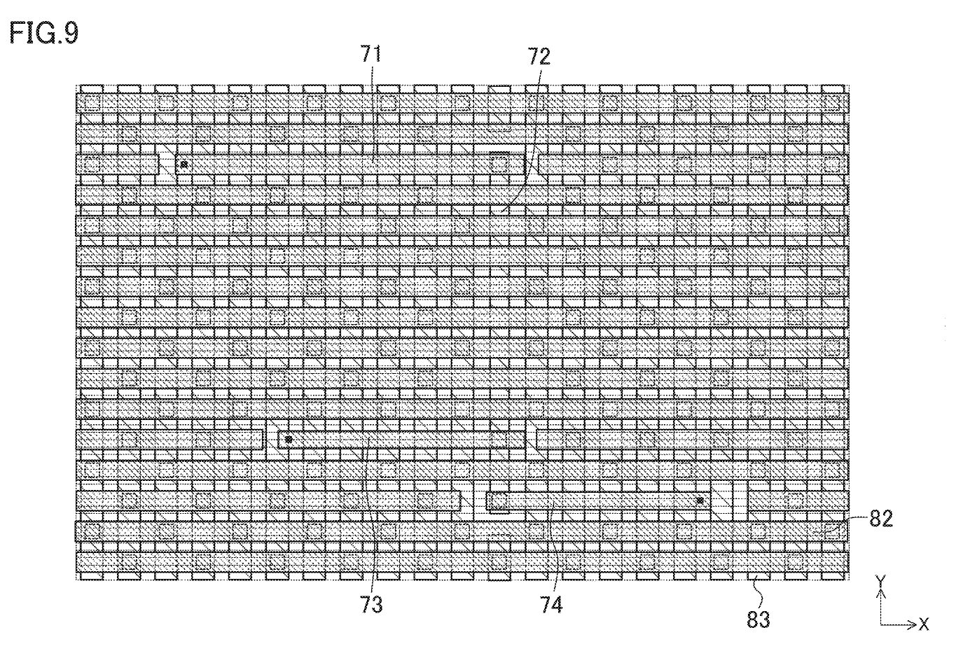

FIG. 8 shows an example of interconnect arrangement in the BM1 interconnect layer in the block layout of FIG. 7. FIG. 9 shows an example of interconnect arrangement in the BM2 and BM3 interconnect layers in the block layout of FIG. 7.

As shown in FIG. 8, in the BM1 interconnect layer, power supply lines 81 extending in the Y direction are placed over the entire block in the region other than the BM1 interconnects that serve as the input terminals and output terminals of the clock buffer cells C1, C2, and C3. As the power supply lines 81, VDD power supply lines and VSS power supply lines are alternately arranged. Note that the power supply lines 81 may be provided under respective cells placed, or may be laid at the time of formation of the block layout.

As shown in FIG. 9, in the BM2 interconnect layer and the BM3 interconnect layer, power supply lines 82 and 83 are placed in a mesh shape over the entire block in the region other than the interconnects 71, 72, 73, and 74 between the clock buffer cells. In FIG. 9, the power supply lines 82 extend in the X direction in the BM2 interconnect layer, and the power supply lines 83 extend in the Y direction in the BM3 interconnect layer.

Note that, in the block layout of FIG. 7, the first-stage clock buffer cell C1 receives the input clock at the M1 interconnect 51 that serves as the front-side input terminal. Alternatively, the clock buffer cell C1 may receive the input clock at a BM1 interconnect that serves as the back-side input terminal. This configuration is effective when the line length from the clock generation circuit to the first-stage clock buffer cell C1 is long.

### Effects of Embodiment

In this embodiment, like normal cells such as the 2-input NAND cell, the clock buffer cell includes the power lines 11 and 12 in the BM0 interconnect layer. Therefore, in the design of the semiconductor integrated circuit device, by placing the clock buffer cells in a similar way to the placement of normal cells, the power lines in the BM0 layer are mutually connected, and this makes the design easy.

Also, the clock buffer cell is a multi-height cell, including a plurality of VDD power supply lines 11 and a plurality of VSS power supply lines 12. Therefore, since the current can be dispersed into a plurality of power supply lines, the problem of a power supply voltage drop can be curbed.

In the clock buffer cell, also, the power supply lines 13a, 13b, 13c, 13d, 14a, and 14b extending in the Y direction are formed in the BM1 interconnect layer. The power supply lines 13a, 13b, 13c, and 13d are connected to the power supply lines 11 in the BM0 interconnect layer. The power supply lines 14a and 14b are connected to the power supply lines 12 in the BM0 interconnect layer. That is, the power supply lines in a mesh shape are formed. This can reduce the resistance of the power supply lines and thus curb a power supply voltage drop.

In the clock buffer cell, as for the signal lines corresponding to the input terminal, the signal lines in the BM1 interconnect layer are larger in line width than the signal lines in the M1 interconnect layer. For example, in the block layout of FIG. 7, the clock buffer cells C2 and C3 receive a clock output from the signal line 61 in the BM1 interconnect layer of the clock buffer cell C1 at the respective signal lines 62 and 63 in the BM1 interconnect layer. Consequently, a large current flows to the signal lines 62 and 63 of the clock buffer cells C2 and C3. Therefore, by increasing the line width of the signal lines corresponding to the input terminal in the BM1 interconnect layer, the problem of electromigration at the input terminal can be curbed.

Also, in the clock buffer cell, as for the signal lines corresponding to the output terminal, the signal lines in the BM1 interconnect layer are larger in line width than the signal lines in the M1 interconnect layer. For example, in the block layout of FIG. 7, the clock buffer cell C1 outputs a clock from the signal line 61 in the BM1 interconnect layer to the clock buffer cells C2 and C3. Consequently, a large current flows through the signal line 61 of the clock buffer cell C1. On the contrary, the clock buffer cells C2 and C3 output a clock from their signal lines 52 and 53 in the M1 interconnect layer to the final-stage buffer cells C4, C5, C6, and C7 of the clock tree. Since the buffer cells C4, C5, C6, and C7 are single-height cells, no large current flows through the signal lines 52 and 53. Therefore, by increasing the line width of the signal lines corresponding to the output terminal in the BM1 interconnect layer, the problem of electromigration at the output terminal can be curbed.

While the clock buffer cell is a multi-height cell having a height 22 times that of normal cells and includes the four buffer parts 21 to 24 having a height three times that of normal cells in the above embodiment, the configuration of the clock buffer cell according to the present disclosure is not limited to this.

According to the present disclosure, in a semiconductor integrated circuit device provided with a clock buffer cell, in a configuration having back-side interconnects, the problems of a power supply voltage drop and electromigration are curbed. The present disclosure is therefore useful for improvement of the performance of a System on Chip (SoC), for example.

1. A semiconductor integrated circuit device, comprising:
a clock buffer cell having an input terminal and an output terminal, the clock buffer cell being a standard cell for transmitting a clock signal,
wherein
the clock buffer cell includes
a transistor,
a first signal line serving as the input terminal, formed in a first interconnect layer located on a front side of the transistor, and
a second signal line serving as the input terminal, formed in a second interconnect layer located on a back side of the transistor, and
a line width of the second signal line is larger than a line width of the first signal line.

2. The semiconductor integrated circuit device of claim 1, further comprising:
a first power supply line supplying a first power supply voltage, formed in a third interconnect layer located between the transistor and the second interconnect layer; and
a second power supply line supplying a second power supply voltage, formed in the third interconnect layer.

3. The semiconductor integrated circuit device of claim 2, wherein
the first and second power supply lines extend in a first direction, and
the first and second signal lines extend in a second direction perpendicular to the first direction.

4. The semiconductor integrated circuit device of claim 1, further comprising
a second clock buffer cell having an input terminal and an output terminal, the second clock buffer cell being a standard cell for transmitting a clock signal,
wherein
the second clock buffer cell includes
a third signal line serving as the output terminal, formed in the second interconnect layer, and
the second signal line of the clock buffer cell is electrically connected with the third signal line of the second clock buffer cell.

5. A semiconductor integrated circuit device, comprising:
a clock buffer cell having an input terminal and an output terminal, the clock buffer cell being a standard cell for transmitting a clock signal,
wherein
the clock buffer cell includes
a transistor,
a first signal line serving as the output terminal, formed in a first interconnect layer located on a front side of the transistor, and
a second signal line serving as the output terminal, formed in a second interconnect layer located on a back side of the transistor, and
a line width of the second signal line is larger than a line width of the first signal line.

6. The semiconductor integrated circuit device of claim 5, further comprising:
a first power supply line supplying a first power supply voltage, formed in a third interconnect layer located between the transistor and the second interconnect layer; and
a second power supply line supplying a second power supply voltage, formed in the third interconnect layer.

7. The semiconductor integrated circuit device of claim 6, wherein
the first and second power supply lines extend in a first direction, and
the first and second signal lines extend in a second direction perpendicular to the first direction.

8. The semiconductor integrated circuit device of claim 5, further comprising
a second clock buffer cell having an input terminal and an output terminal, the second clock buffer cell being a standard cell for transmitting a clock signal,
wherein
the second clock buffer cell includes
a third signal line serving as the input terminal formed in the second interconnect layer, and
the second signal line of the clock buffer cell is electrically connected with the third signal line of the second clock buffer cell.
